(19) United States
(12) Patent Application Publication
(10) Pub. No.: US 2025/0228148 A1
(43) Pub. Date: Jul. 10, 2025

(54) RESISTIVE MEMORY DEVICE, SEMICONDUCTOR DEVICE INCLUDING THE SAME, AND METHOD FOR MANUFACTURING THE SAME

(71) Applicant: TAIWAN SEMICONDUCTOR MANUFACTURING COMPANY, LTD., Hsinchu (TW)

(72) Inventors: Fu-Chen CHANG, Hsinchu (TW); Wen-Ting CHU, Hsinchu (TW); Kuo-Chi TU, Hsinchu (TW); Sheng-Hung SHIH, Hsinchu (TW); Chu-Jie HUANG, Hsinchu (TW)

(73) Assignee: TAIWAN SEMICONDUCTOR MANUFACTURING COMPANY, LTD., Hsinchu (TW)

(21) Appl. No.: 18/404,211

(22) Filed: Jan. 4, 2024

(51) Int. Cl. H10N 70/00; H10B 63/00

(52) U.S. Cl. CPC H10N 70/8833; H10B 63/30; H10N 70/021; H10N 70/063; H10N 70/066; H10N 70/068; H10N 70/821; H10N 70/841

(57) ABSTRACT

A resistive memory device includes a bottom electrode, a switching layer disposed over the bottom electrode, a top electrode disposed over the switching layer, and an auxiliary layer disposed between the switching layer and one of the top electrode and the bottom electrode. The one of the top electrode and the bottom electrode includes a metal and is a relatively inert electrode in comparison with the other one of the top electrode and the bottom electrode. The auxiliary layer includes a nitride of the metal.

### BACKGROUND

With the advancement of semiconductor technology and industry, non-volatile memory which is able to store data in the absence of power is incorporated as a storage element in modern day integrated circuit devices. Resistive random access memory (RRAM) which can be switched between a high resistance state and a low resistance state to store data is a candidate for the next generation of non-volatile memory.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a schematic view of a resistive memory device that includes an auxiliary layer in accordance with some embodiments.

FIG. 2 illustrates a schematic view of a semiconductor device that includes a resistive memory device where an auxiliary layer is sandwiched between a switching layer and a bottom electrode in accordance with some embodiments.

FIG. 3 illustrates a schematic view of a semiconductor device that includes a memory cell in accordance with some embodiments.

FIG. 4 is a flow diagram illustrating a method for manufacturing a semiconductor device in accordance with some embodiments, in which a resistive memory device includes an auxiliary layer.

FIGS. 5 to 16 illustrate schematic views of some intermediate stages of the method depicted in FIG. 4 in accordance with some embodiments.

FIG. 17 illustrates a schematic view of a semiconductor device that includes a resistive memory device where an auxiliary layer is sandwiched between a switching layer and a top electrode in accordance with some embodiments.

FIGS. 18 to 19 illustrate schematic views of some intermediate stages related to manufacturing of the semiconductor device depicted in FIG. 17 in accordance with some embodiments.

FIG. 20 illustrates a schematic view of a semiconductor device that includes a resistive memory device where a top electrode is shorter than a switching layer in accordance with some embodiments.

FIGS. 21 to 25 illustrate schematic views of some intermediate stages related to manufacturing of the semiconductor device depicted in FIG. 20 in accordance with some embodiments.

FIG. 26 illustrates a schematic view of a semiconductor device that includes a resistive memory device where each of a top electrode, a switching layer, an auxiliary layer and a bottom electrode has a gull-wing shape in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “downwardly,” “upper,” “lower,” “over,” “under,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, and other numerical values used in the specification and claims, are to be understood as being modified in all instances by the term “about” even though the term “about” may not expressly appear with the value, amount or range. Accordingly, unless indicated to the contrary, the numerical parameters set forth in the following specification and attached claims are not and need not be exact, but may be approximate and/or larger or smaller as desired, reflecting tolerances, conversion factors, rounding off, measurement error and the like, and other factors known to those of skill in the art depending on the desired properties sought to be obtained by the presently disclosed subject matter. For example, the term “about,” when referring to a value can be meant to encompass variations of, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions.

Among next-generation memories, resistive random access memory (RRAM) has great potential to replace current flash memory which is used extensively for embedded applications. An RRAM includes a metal-insulator-metal structure generally referred to as the MIM structure and including an insulating layer sandwiched between two metal electrodes. An RRAM is initially in a high resistance state (HRS) after being manufactured, and a high voltage pulse is then applied to enable formation of conductive paths (also known as filaments) in the insulating layer to switch the RRAM from the HRS to a low resistance state (LRS). This process which occurs because of soft breakdown of the MIM structure is referred to as “electroforming,” and the high voltage pulse at which this process occurs is referred to as a “forming voltage.” To switch the RRAM from the LRS to the HRS, a voltage pulse referred to as a “reset voltage” is applied to the RRAM to enable this switching transition, and this process is referred to as a “reset process.” The RRAM can be changed from the HRS to the LRS upon application of another voltage pulse which is referred to as a “set voltage,” and this process is referred to as a “set process.” The insulating layer of the RRAM may be referred to as a switching layer in view of the resistance switching behavior. The reset voltage and the set voltage may be collectively referred to as operating voltages. The HRS generally corresponds to a logic value 0 while the LRS generally corresponds to a logic value 1.

With the dramatic advances in integrated circuit (IC) design as predicted by the Moore's law, new generations of ICs have smaller and more complex structures, and the device dimensions of transistors continue to shrink. Because of the shrinkage of the channel length, the operating voltage of a transistor becomes smaller and smaller, which may be less than a forming voltage or operating voltages of an RRAM, thereby making it difficult to realize a 1-transistor 1-RRAM (1T-1R) cell configuration. Moreover, the forming voltage of an RRAM will increase as a size of the RRAM shrinks, thereby making it even harder for the RRAM to operate together with a transistor, which usually requires a lower operating voltage. Therefore, how to reduce the forming voltage and the operating voltages, as well as a switching power, is an important issue in scaling down an RRAM. Furthermore, how to promote endurance, i.e., the number of write/erase cycles, of an RRAM is also of great concern.

This disclosure is related to improving characteristics (e.g., forming voltage, operating voltages, switching power, endurance, etc.) of a resistive memory device, which includes a top electrode, a bottom electrode and a switching layer, by inserting an auxiliary layer between the switching layer and one of the top electrode and the bottom electrode. The one of the top electrode and the bottom electrode is a relatively inert electrode in comparison with the other one of the top electrode and the bottom electrode, which is a relatively active electrode. The relatively inert electrode is made of a material that is less likely to react with oxygen ions, and the relatively active electrode is made of a material that is more likely to react with oxygen ions. In some embodiments, the one of the top electrode and the bottom electrode includes a metal, and the auxiliary layer includes a nitride of the metal. In some embodiments, the one of the top electrode and the bottom electrode includes ruthenium, and the auxiliary layer includes ruthenium nitride.

With the auxiliary layer sandwiched between the switching layer and the one of the top electrode and the bottom electrode (i.e., the relatively inert electrode), when the resistive memory device is applied with a voltage, oxygen ions generated in the switching layer are more prone to moving toward the other one of top electrode and the bottom electrode that is the relatively active electrode, and oxygen vacancies are more prone to accumulating in the switching layer to switch the resistive memory device to the LRS, thereby decreasing the forming voltage utilized for the electroforming and the set voltage utilized for the set process. In this way, the switching power consumed by the resistive memory device may be reduced. Moreover, the endurance of the resistive memory device is found to be promoted with insertion of the auxiliary layer between the switching layer and the relatively inert electrode.

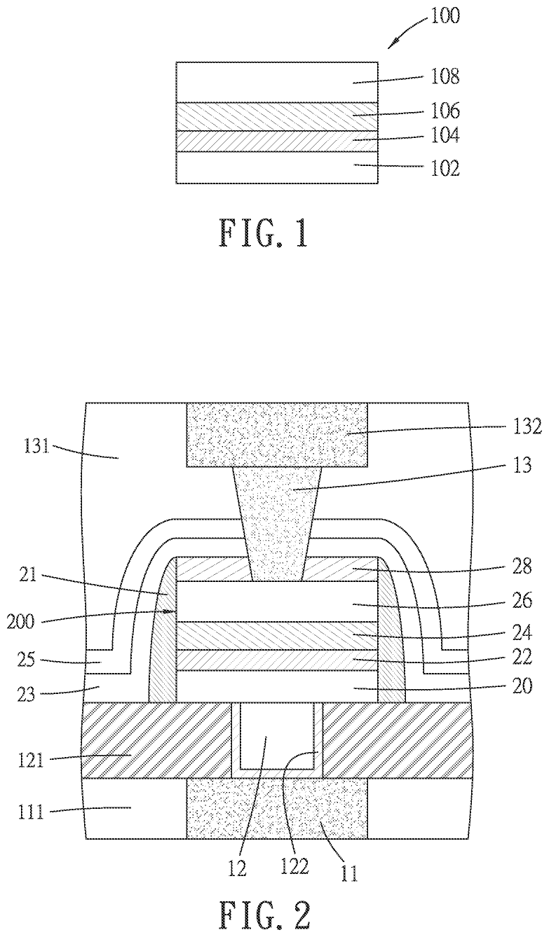

FIG. 1 is a schematic sectional view illustrating a resistive memory device 100 in accordance with some embodiments. The resistive memory device 100 reversibly changes between the HRS and the LRS depending upon a voltage, i.e., the set voltage or the reset voltage, applied across the resistive memory device 100. In some embodiments, the resistive memory device 100 is a resistive random-access memory (RRAM), but the resistive memory device 100 may be other types of memory device in other embodiments. The resistive memory device 100 includes a bottom electrode 102, an auxiliary layer 104 overlying the bottom electrode 102, a switching layer 106 overlying the auxiliary layer 104, and a top electrode 108 overlying the switching layer 106.

FIG. 2 is a schematic sectional view illustrating a semiconductor device that includes a resistive memory device 200 in accordance with some embodiments. The resistive memory device 200 is similar to the resistive memory device 100 shown in FIG. 1 and also includes a bottom electrode 20, an auxiliary layer 22, a switching layer 24 and a top electrode 26. The resistive memory device 200 is disposed on a bottom electrode via (BEVA) 12 and an etch stop layer 121 that accommodates the BEVA 12. The BEVA 12 and the etch stop layer 121 overlie a lower wire 11 and a lower interlayer dielectric (ILD) layer 111 in which the lower wire 11 is formed. The BEVA 12 extends downwardly from the bottom electrode 20 of the resistive memory device 200, through the etch stop layer 121, to the lower wire 11. A barrier layer 122 cups an underside of the BEVA 12 so as to line a bottom and sidewalls of the BEVA 12. The barrier layer 122 contacts the BEVA 12, the lower wire 11 and the etch stop layer 121, and blocks a material of the BEVA 12 from migrating out of the BEVA 12 to surrounding structures (e.g., the lower wire 11 underneath the BEVA 12).

In some embodiments, the lower ILD layer 111 includes, for example but not limited to, silicon dioxide, silicon nitride, silicon oxynitride, silicon carbide, a low-k dielectric material (e.g., a dielectric with a dielectric constant k less than about 3.9, 3.1, 2.0, or 1.1), or combinations thereof. Other suitable materials for the lower ILD layer 111 are within the contemplated scope of the present disclosure. In some embodiments, the lower wire 11 includes, for example but not limited to, copper, aluminum, aluminum copper, other metals, other conductive materials, or other suitable materials.

In some embodiments, the BEVA 12 includes, for example but not limited to, titanium, titanium nitride, tantalum, tantalum nitride, tungsten, ruthenium, other conductive materials, or combinations thereof. Other suitable materials for the BEVA 12 are within the contemplated scope of the present disclosure. In some embodiments, the etch stop layer 121 includes, for example but not limited to, silicon carbide, other etch resistance materials, or combinations thereof. Other suitable materials for the etch stop layer 121 are within the contemplated scope of the present disclosure. In some embodiments, the barrier layer 122 may be a conductive oxide, nitride, or oxynitride of a metal selected from the group consisting of Al, Mn, Co, Ti, Ta, W, Ni, Sn, Mg. In some embodiments, the barrier layer 122 includes, for example but not limited to, titanium nitride, tantalum nitride, tantalum, or other conductive barrier materials. Other suitable materials for the barrier layer 122 are within the contemplated scope of the present disclosure.

The bottom electrode 20 overlies the BEVA 12, the etch stop layer 121 and the barrier layer 122. In some embodiments, the bottom electrode 20 directly contacts a top surface of the BEVA 12. The auxiliary layer 22 overlies the bottom electrode 20, the switching layer 24 overlies the auxiliary layer 22, and the top electrode 26 overlies the switching layer 24. The switching layer 24 reversibly changes between the HRS and the LRS depending upon a voltage, i.e., the set voltage or the reset voltage, applied across the resistive memory device 200. In some embodiments, the bottom electrode 20 is a relatively inert electrode in comparison with the top electrode 26, which means that the top electrode 26 is a more active electrode with respect to the bottom electrode 20. In some embodiments, the bottom electrode 20 includes a metal, and the auxiliary layer 22 includes a nitride of the metal. In some embodiments, the bottom electrode 20 includes ruthenium, and the auxiliary layer 22 includes ruthenium nitride. Other suitable materials for the bottom electrode 20 and the auxiliary layer 22 are within the contemplated scope of the present disclosure. In some embodiments, the bottom electrode 20 includes the same material as the BEVA 12. For example, the BEVA 12 and the bottom electrode 20 both include ruthenium. In some embodiments, the bottom electrode 20 is integrated with the BEVA 12. For example, the bottom electrode 20 and the BEVA 12 may be formed by the same deposition process.

In some embodiments, the bottom electrode 20 has a thickness that ranges from about 0.1 nanometers (nm) to about 500 nm, and the auxiliary layer 22 has a thickness that ranges from about 0.1 nm to about 10 nm. It is noted that if the thickness of the auxiliary layer 22 is too small (e.g., less than 0.1 nm), the presence of the auxiliary layer 22 might not achieve the effects of improving endurance of the resistive memory device 200 and decreasing the forming voltage, the set voltage and/or the switching power of the resistive memory device 200. On the other hand, if the thickness of the auxiliary layer 22 is too large (e.g., greater than 10 nm), the auxiliary layer 22 would have an undesirably high resistance and cause too much voltage drop across the auxiliary layer 22, making the resistive memory device 200 not able to effectively drop a voltage across the switching layer 24. In other words, too large of a thickness of the auxiliary layer 22 might lead to a voltage division that the resistive memory device 200 cannot operate normally. In some embodiments, a ratio of the thickness of the bottom electrode 20 to the thickness of the auxiliary layer 22 ranges from about 0.1:1 to about 5000:1.

In some embodiments where the resistive memory device 200 is an RRAM, the switching layer 24 includes, for example but not limited to, an oxide-based material (e.g., hafnium oxide, zirconium oxide or aluminum oxide), a nitride-based material (e.g., silicon nitride or aluminum nitride), other high-k dielectric materials (e.g., a dielectric with a dielectric constant k greater than about 3.9, 5.1, 10.0, 15.1 or 20.0), or combinations thereof. Other suitable materials for the switching layer 24 are within the contemplated scope of the present disclosure. In some embodiments, the top electrode 26 is a relatively active electrode in comparison with the bottom electrode 20, and includes, for example but not limited to, copper, aluminum, tungsten, tantalum, titanium, compounds thereof (e.g., titanium nitride or tantalum nitride), other conductive materials, or combinations thereof. Other suitable materials for the top electrode 26 are within the contemplated scope of the present disclosure. In some embodiments, the switching layer 24 has a thickness that ranges from about 0.1 nm to about 100 nm, and the top electrode 26 has a thickness that ranges from about 0.1 nm to about 500 nm.

A hard mask 28 overlies the resistive memory device 200, and a spacer 21 overlies the etch stop layer 121. The spacer 21 includes a pair of spacer segments respectively bordering opposite sidewalls of the resistive memory device 200. In some embodiments, the spacer segments respectively border opposite sidewalls of the hard mask 28 that are aligned with the opposite sidewalls of the resistive memory device 200. In some embodiments, the hard mask 28 and the spacer 21 each include, for example but not limited to, silicon oxide, silicon nitride, silicon oxynitride, other suitable dielectric material, or combinations thereof.

A capping layer 23 overlies the hard mask 28 and the etch stop layer 121, and covers sidewalls of the spacer 21. Further, a buffer layer 25 overlies the capping layer 23. In some embodiments, the capping layer 23 serves as an etch stop layer for a later etching process related to formation of a top electrode via (TEVA) 13, and the buffer layer 25 is used for promoting adhesion between a structure that includes the resistive memory device 200 underneath the buffer layer 25 and an upper ILD layer 131 that is to be later formed over the buffer layer 25. In some embodiments, the capping layer 23 includes, for example but not limited to, silicon carbide, silicon oxide, other oxides, other dielectrics, or combinations thereof. Other suitable materials for the capping layer 23 are within the contemplated scope of the present disclosure. In some embodiments, the buffer layer 25 includes, for example but not limited to, tetraethoxysilane (TEOS) or other materials suitable for adhesion.

The upper ILD layer 131 overlies the buffer layer 25, and accommodates the TEVA 13 and an upper wire 132 that is located above and connected to the TEVA 13. The TEVA 13 is disposed directly between the upper wire 132 and the resistive memory device 200, and extends from the upper wire 132, through the upper ILD layer 131, to the resistive memory device 200. In the illustrated embodiment, the TEVA 13 further extends through the buffer layer 25, the capping layer 23 and the hard mask 28 to contact the top electrode 26. In some embodiments, the TEVA 13 may be sunken into (not shown) a top surface of the top electrode 26 because of over etching. In some embodiments, the upper ILD layer 131 includes, for example but not limited to, silicon dioxide, silicon nitride, silicon carbide, a low-k dielectric material, other dielectrics, or combinations thereof. In some embodiments, the TEVA 13 includes, for example but not limited to, copper, aluminum, tungsten, ruthenium, aluminum copper, other conductive materials, or combinations thereof. In some embodiments, the upper wire 132 includes, for example but not limited to, copper, aluminum, aluminum copper, other conductive materials, or combinations thereof. Other suitable materials for the upper ILD layer 131, the TEVA 13 and the upper wire 132 are within the contemplated scope of the present disclosure.

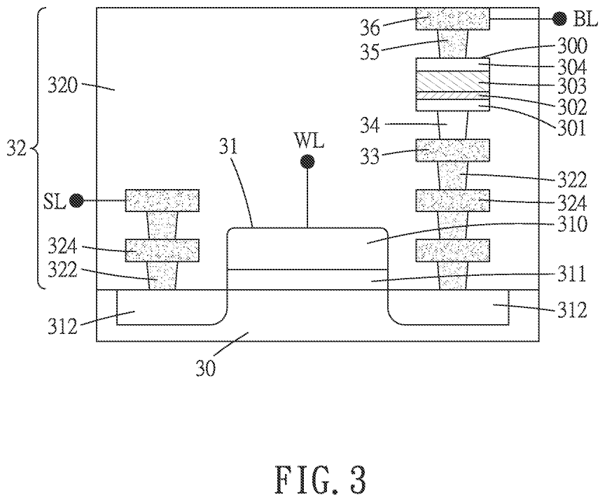

FIG. 3 is a schematic diagram of a semiconductor device that includes a memory cell in accordance with some embodiments. The memory cell includes a resistive memory device 300 and an access device 31 that cooperate to realize a 1-transistor 1-RRAM (1T-1R) cell configuration. The resistive memory device 300 is electrically connected to the access device 31. In some embodiments, the memory cell is one of many memory cells that define a memory cell array (not shown). The access device 31 facilitates access or selection of the resistive memory device 300 in the memory cell. In some embodiments, the resistive memory device 300 is similar to the resistive memory device 100 of FIG. 1 or the resistive memory device 200 of FIG. 2 and includes a bottom electrode 301, an auxiliary layer 302, a switching layer 303 and a top electrode 304, and the access device 31 is a metal-oxide-semiconductor field-effect transistor (MOSFET) that includes a gate electrode feature 310, a gate oxide 311 underlying the gate electrode feature 310, and a pair of source/drain features 312 disposed under and located on opposite sides of the gate electrode feature 310. In some embodiments, the gate electrode feature 310 includes, for example but not limited to, polysilicon, a metal, a metal silicide, other types of conductive materials, other suitable materials for a gate electrode, or combinations thereof; the gate oxide 311 includes, for example but not limited to, silicon oxide, silicon nitride, silicon oxynitride, silicon carbide, other suitable materials for a gate oxide, or combinations thereof. It is noted that each of the source/drain features 312 may refer to a source or a drain, individually or collectively depending upon the context. In a case where the access device 31 is an n-type MOSFET, each of the source/drain features 312 is a heavily doped n-type (N+) region. However, the implementation of the resistive memory device 300 is not limited to the above discussion, and may be other types of RRAM, and the implementation of the access device 31 is not limited to the above discussion, and may be other types of semiconductor device, such as an insulated gate field-effect transistor (IGFET).

In addition to the memory cell, the semiconductor device further includes a semiconductor substrate 30. The semiconductor substrate 30 supports the access device 31, and partially defines the access device 31 (e.g., a body and/or the source/drain features 312 of the access device 31). In some embodiments, the semiconductor substrate 30 may be, for example but not limited to, a bulk silicon substrate, a silicon-on-insulator (SOI) substrate (e.g., silicon germanium on insulator (SGOI)), or other types of semiconductor substrate. Specifically, the semiconductor substrate 30 may include, for example but not limited to, an elemental semiconductor or a compound semiconductor. In some embodiments, the elemental semiconductor includes a single species of atoms, such as silicon (Si) or germanium (Ge) in column XIV of the periodic table, and may be in crystal form, polycrystalline form, or amorphous form. Other suitable elemental semiconductor materials are within the contemplated scope of the present disclosure. In some embodiments, the compound semiconductor includes two or more elements, and examples thereof may include, but not limited to, silicon carbide (SiC), gallium arsenide (GaAs), gallium phosphide (GaP), indium phosphide (InP), indium arsenide (InAs), indium antimonide (InSb), silicon germanium (SiGe), gallium arsenide phosphide (GaAsP), aluminum indium arsenide (AlInAs), aluminum gallium arsenide (AlGaAs), gallium indium arsenide (GaInAs), gallium indium phosphide (GaInP), and gallium indium arsenide phosphide (GaInAsP). Other suitable compound semiconductor materials are within the contemplated scope of the present disclosure. The compound semiconductor may have a gradient feature in which the compositional ratio thereof changes from one location to another location therein. The compound semiconductor may be formed over a silicon substrate. The compound semiconductor may be strained. In some embodiments, the semiconductor substrate 30 may include a multilayer compound semiconductor structure. Generally, an SOI substrate includes a layer of a semiconductor material such as epitaxial silicon, germanium, silicon germanium, or combinations thereof. Other suitable semiconductor materials are within the contemplated scope of the present disclosure. The SOI substrate may be doped with a P-type dopant, for example, but not limited to, boron (Br), aluminum (Al), or gallium (Ga). Other suitable dopant materials are within the contemplated scope of the present disclosure. Alternatively, the SOI substrate may be doped with an N-type dopant, for example, but not limited to, nitrogen (N), phosphorous (P), or arsenic (As). Other suitable dopant materials are within the contemplated scope of the present disclosure.

The semiconductor device of FIG. 3 further includes a back end of line (BEOL) interconnect structure 32 that overlies the semiconductor substrate 30 and accommodates the resistive memory device 300. The BEOL interconnect structure 32 includes a plurality of conductive features and a dielectric stack 320. The conductive features are stacked in the dielectric stack 320 to define conductive paths interconnecting the resistive memory device 300, the access device 31, and, if any, other devices of the semiconductor device, such as a source line (SL), a word line (WL) and bit line (BL). The plurality of conductive features include a lower wire 33, a BEVA 34, a TEVA 35 and an upper wire 36. The resistive memory device 300 rests on the BEVA 34 and underlies the TEVA 35. The BEVA 34 is connected to the lower wire 33, and the TEVA 35 is connected to the upper wire 36. In some embodiments, each of the lower wire 33, the BEVA 34, the TEVA 35 and the upper wire 36 is similar to a respective one of the lower wire 11, the BEVA 12, the TEVA 13 and the upper wire 132 as shown in and described with respect to FIG. 2, and details of the same are thus omitted herein for the sake of brevity. The plurality of conductive features further include a plurality of additional vias 322 and a plurality of additional wires 324. In some embodiments, the additional vias 322 and the additional wires 324 include, for example but not limited to, copper, aluminum, tungsten, aluminum copper, other conductive materials, or combinations thereof. Other suitable materials for the additional vias 322 and the additional wires 324 are within the contemplated scope of the present disclosure.

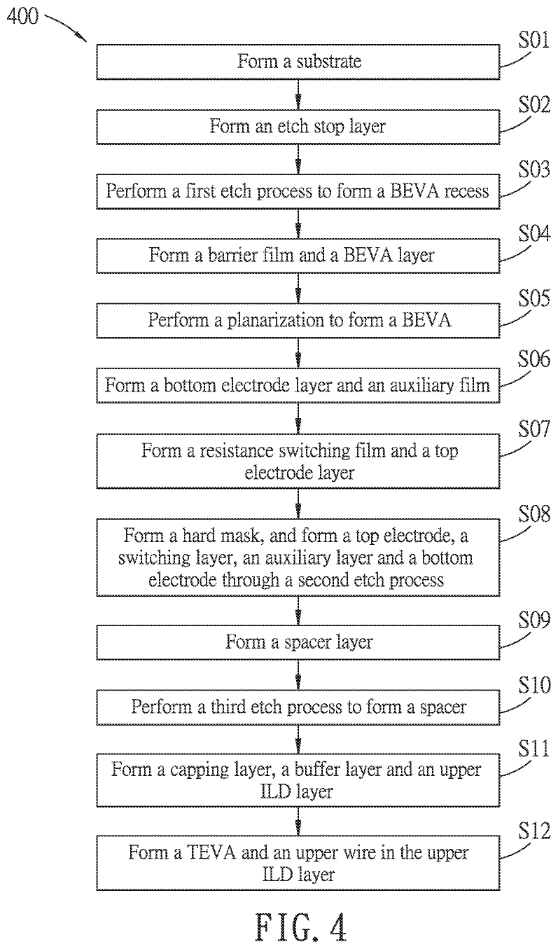

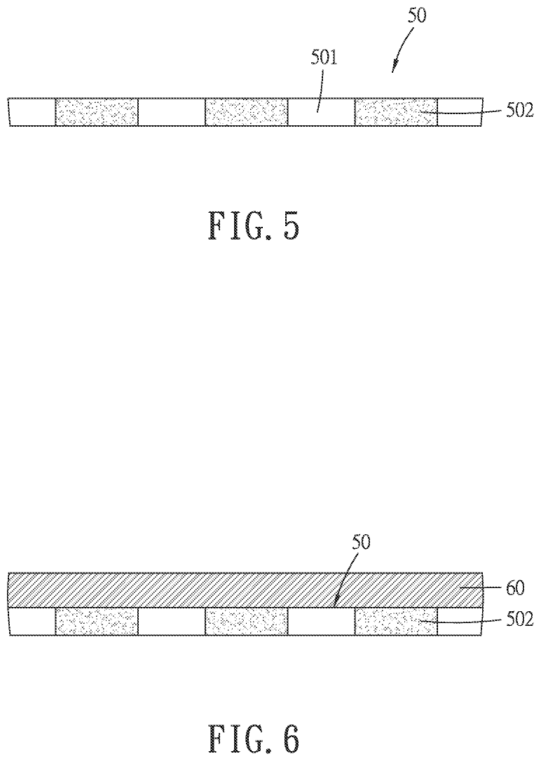

FIG. 4 is a flow diagram illustrating a method 400 for manufacturing a semiconductor device that includes a resistive memory device (for example, the resistive memory device 200 shown in FIG. 2 or a resistive memory device 700 shown in FIG. 12 or 16). The resistive memory device includes an auxiliary layer disposed between a switching layer and one of a top electrode and a bottom electrode in accordance with some embodiments. FIGS. 5 to 16 illustrate schematic sectional views of some intermediate stages of the method 400 in accordance with some embodiments. Some portions may be omitted in FIGS. 5 to 16 for the sake of brevity. Additional steps can be provided before, after or during the method 400, and some of the steps described herein may be replaced by other steps or be eliminated. Similarly, further additional features may be present in the semiconductor device, and/or features present may be replaced or eliminated in additional embodiments.

Referring to FIG. 4 and the example illustrated in FIG. 5, the method 400 begins at step S01, where a substrate 50 is formed. The substrate 50 includes a lower ILD layer 501 and at least one lower wire 502 (three lower wires are exemplarily shown). In some embodiments, the substrate 50 may further include the semiconductor substrate 30 of FIG. 3, a portion of the BEOL interconnect structure 32 of FIG. 3 that is under the BEVA 34, the access device 31 of FIG. 3, or combinations thereof. In some embodiments, the lower ILD layer 501 includes, for example but not limited to, silicon oxide, silicon nitride, a low-k dielectric material, other dielectrics, other suitable materials for an ILD layer, or combinations thereof. The lower wire 502 is recessed into the lower ILD layer 501 in such a manner that a top surface of the lower wire 502 is even (levelled) or substantially even with a top surface of the lower ILD layer 501. In some embodiments, the lower wire 502 includes, for example but not limited to, copper, aluminum, titanium, tantalum, aluminum copper, titanium nitride, tantalum nitride, other conductive materials, other suitable materials for a conductive wire, or combinations thereof.

Referring to FIG. 4 and the example illustrated in FIG. 6, the method 400 proceeds to step S02, where an etch stop layer 60 is formed over the substrate 50 and covers the substrate 50. In some embodiments, the etch stop layer 60 may include the same or similar material (e.g., silicon carbide) as the etch stop layer 121 of FIG. 2, and details related to the material of the etch stop layer 60 are omitted herein for the sake of brevity. In some embodiments, a process for forming the etch stop layer 60 includes, chemical vapor deposition (CVD), physical vapor deposition (PVD), other suitable deposition process, or combinations thereof.

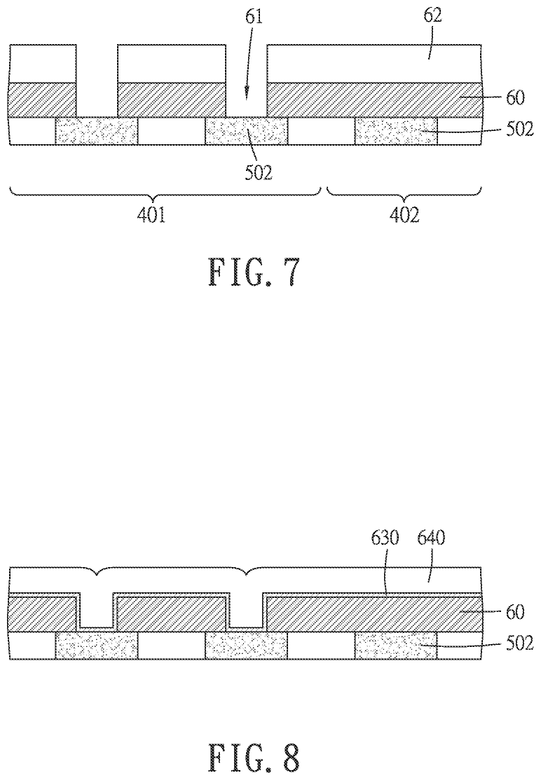

Referring to FIG. 4 and the example illustrated in FIG. 7, the method 400 proceeds to step S03, where a first etch process is performed on the etch stop layer 60 to form at least one BEVA recess 61 (two BEVA recesses are exemplarily shown) that is located over and exposes the lower wire 502. In some embodiments, the first etch process includes forming a photoresist mask 62 on the etch stop layer 60. The photoresist mask 62 may be formed by, for example but not limited to, depositing a photoresist layer on the etch stop layer 60 and patterning the photoresist layer with a layout corresponding to the BEVA recess 61. The deposition may be implemented by, for example but not limited to, spin coating or other suitable deposition processes, and the patterning may be implemented by, for example but not limited to, photolithography or other suitable patterning processes. One or more first etchants are applied to the etch stop layer 60 until the lower wire 502 is reached, at which point formation of the BEVA recess 61 is finished. The photoresist mask 62 is then removed. It is noted that the BEVA recess 61 is formed at a location where a resistive memory device is later to be formed and this location may be referred to as a memory region 401, and the location where no BEVA recess is formed over the lower wire 502 is referred to as a logic region 402.

Referring to FIG. 4 and the example illustrated in FIG. 8, the method 400 proceeds to step S04, where a barrier film 630 is formed on the etch stop layer 60 and the lower wire 502 exposed through the BEVA recess 61 (see FIG. 7), and a BEVA layer 640 is subsequently formed on the barrier film 630 and fills the BEVA recess 61. In some embodiments, the barrier film 630 may include the same or similar material as the barrier layer 122 of FIG. 2, and details related to the material of the barrier film 630 are omitted herein for the sake of brevity. In some embodiments, the barrier film 630 is conformally deposited to cover the etch stop layer 60, the lower wire 502, and the BEVA recess 61. The conformal deposition may be performed by a suitable deposition process as known to those skilled in the art of semiconductor fabrication, for example but not limited to, CVD, plasma enhanced chemical vapor deposition (PECVD), atomic layer deposition (ALD), or plasma enhanced atomic layer deposition (PEALD). In some embodiments, the BEVA layer 640 may include the same or similar material as the BEVA 12 of FIG. 2, and details related to the material of the BEVA layer 640 are omitted herein for the sake of brevity. In some embodiments, the BEVA layer 640 is formed by, for example but not limited to, CVD, PVD, sputtering, electroless plating, electroplating, other plating or deposition processes. Other suitable processes for forming the BEVA layer 640 are within the contemplated scope of the present disclosure.

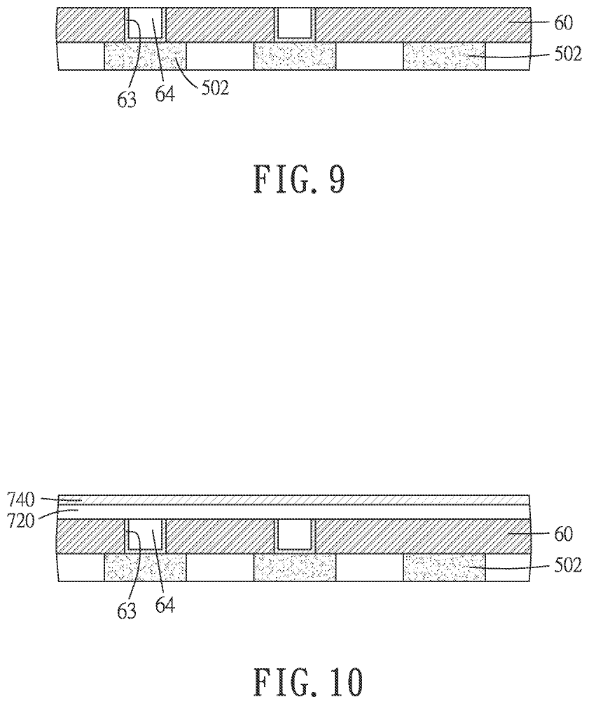

Referring to FIG. 4 and the example illustrated in FIG. 9, the method 400 proceeds to step S05, where a planarization process is performed on the BEVA layer 640 and the barrier film 630 (see FIG. 8) until the etch stop layer 60 is reached, to form at least one BEVA 64 (two BEVAs are exemplarily shown) from the BEVA layer 640 and at least one barrier layer 63 from the barrier film 630. The BEVA 64 is located in the BEVA recess 61 (see FIG. 7), and the barrier layer 63 cups an underside of the BEVA 64. The barrier layer 63 contacts the BEVA 64, the lower wire 502 and the etch stop layer 60, and blocks the material of the BEVA 64 from migrating to surrounding structures (e.g., the lower wire 502). In some embodiments, a top surface of the BEVA 64 is flat and even with a top surface of the etch stop layer 60, and the BEVA 64 is formed with a width that is uniform or substantially uniform in a direction from the lower wire 502 to the top surface of the BEVA 64. In some embodiments, the planarization process is implemented by chemical mechanical polishing (CMP) or other suitable planarization processes.

Referring to FIG. 4 and the example illustrated in FIG. 10, the method 400 proceeds to step S06, where a bottom electrode layer 720 is formed on the etch stop layer 60, the BEVA 64 and the barrier layer 63, and an auxiliary film 740 is formed on the bottom electrode layer 720. In some embodiments, the bottom electrode layer 720 is formed to cover the etch stop layer 60, the BEVA 64 and the barrier layer 63, and the auxiliary film 740 is formed to cover the bottom electrode layer 720. In some embodiments, the bottom electrode layer 720 is conductive and includes a metal, and the auxiliary film 740 includes a nitride of the metal. In some embodiments, the bottom electrode layer 720 includes ruthenium, and the auxiliary film 740 includes ruthenium nitride. Other suitable materials for the bottom electrode layer 720 and the auxiliary film 740 are within the contemplated scope of the present disclosure. In some embodiments, the bottom electrode layer 720 is formed by, for example but not limited to, CVD, PVD, electroless plating, electroplating, sputtering, other suitable plating or deposition process, or combinations thereof. Regarding formation of the auxiliary film 740 on the bottom electrode layer 720, many approaches may be adopted. One approach is to perform a nitriding process on the bottom electrode layer 720 that includes a metal (e.g., ruthenium). The nitriding process is to defuse nitrogen into an upper portion of the bottom electrode layer 720 such that the upper portion of the bottom electrode layer 720 is nitrided to form the auxiliary firm 740 that includes a nitride of the metal (e.g., ruthenium nitride). Another approach is to directly deposit the auxiliary film 740, such as a film of ruthenium nitride, on a top surface of the bottom electrode layer 720 by using, for example but not limited to, PVD, ALD, CVD, other suitable deposition processes, or combinations thereof.

The nitriding process includes gas nitriding and plasma nitriding. In some embodiments, when gas nitriding is used, a nitrogen-rich gas, such as nitrogen gas or ammonia which would later disassociate into nitrogen and hydrogen during the process, is introduced at a preset flow rate to contact the bottom electrode layer 720 under a preset temperature, and the nitrogen then diffuses onto the upper portion of the bottom electrode layer 720 to create a nitride layer (i.e., the auxiliary film 740). In some embodiments, when plasma nitriding is used, intense electric fields are applied to generate ionized molecules (i.e., plasma) of a nitrogen carrying gas, such as nitrogen gas, around the upper portion of the bottom electrode layer 720, and the nitrogen plasma interacts with the upper portion of the bottom electrode layer 720 to form the auxiliary film 740. In some embodiments, the plasma nitriding is conducted under conditions that may involve, for example but not limited to, (i) a bias voltage that may be set from about 70 volts to about 200 volts, (ii) a process time that may range from about 20 seconds to about 60 seconds, and (iii) a flow rate of hydrogen gas that may range from about 10 standard cubic centimeters per minute (sccm) to about 100 sccm. It is noted that different parameters related to the nitriding process may be used to form different properties of the auxiliary film 740, and the parameters used to conduct the nitriding process are not limited to the disclosure herein and may vary in other embodiments.

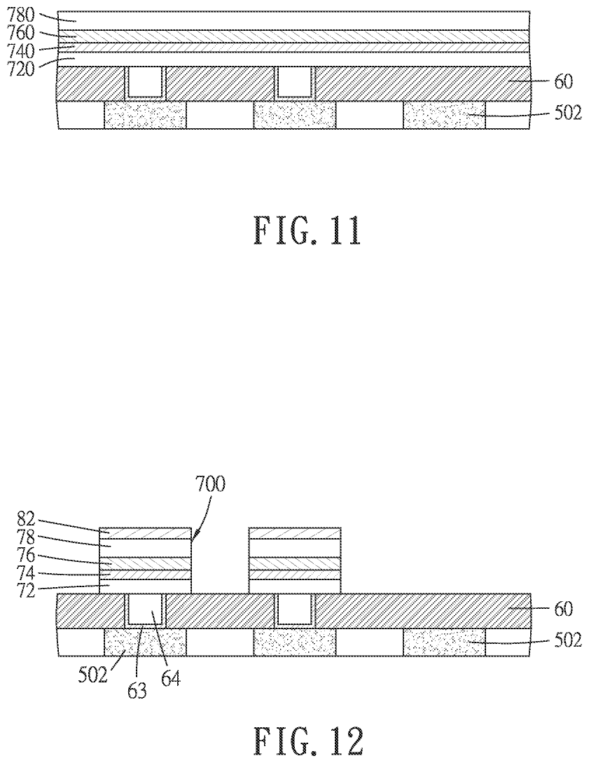

Referring to FIG. 4 and the example illustrated in FIG. 11, the method 400 proceeds to step S07, where a resistance switching film 760 is formed on the auxiliary film 740, and a top electrode layer 780 is formed on the resistance switching film 760. In some embodiments, the resistance switching film 760 is formed to cover the auxiliary film 740, and the top electrode layer 780 is formed to cover the resistance switching film 760. In some embodiments, the resistance switching film 760 includes, for example but not limited to, an oxide-based material (e.g., hafnium oxide, zirconium oxide or aluminum oxide), a nitride-based material (e.g., silicon nitride or aluminum nitride), other high-k dielectric materials, or combinations thereof. Other suitable materials for the resistance switching film 760 are within the contemplated scope of the present disclosure. In some embodiments, the top electrode layer 780 includes a relatively active material in terms of oxygen ions when compared to the bottom electrode layer 720, and examples of the relatively active material include, copper, aluminum, tungsten, tantalum, titanium, compounds thereof (e.g., titanium nitride or tantalum nitride), other conductive materials, and combinations thereof. Other suitable materials for the top electrode layer 780 are within the contemplated scope of the present disclosure. In some embodiments, each of the resistance switching film 760 and the top electrode layer 780 is formed by, for example but not limited to, CVD, PVD, electroless plating, electroplating, sputtering, other suitable plating or deposition process, or combinations thereof.

Referring to FIG. 4 and the example illustrated in FIG. 12, the method 400 proceeds to step S08, where at least one hard mask 82 is formed to cover at least one memory device part of the top electrode layer 780 (see FIG. 11) that overlies the BEVA 64 and the lower wire 502 (two hard masks and two memory device parts are exemplarily shown). In some embodiments, the hard mask 82 includes, for example but not limited to, silicon carbide, silicon nitride, other nitrides, other dielectrics, other suitable materials, or combinations thereof. In some embodiments, the hard mask 82 is formed by depositing a hard mask layer (not shown) on the top electrode layer 780 and patterning the hard mask layer into the hard mask 82. The deposition may be implemented by, for example but not limited to, CVD, PVD, or other suitable deposition processes, and the patterning may be implemented by, for example but not limited to, photolithography or other suitable patterning processes, and an etching process.

Subsequently, a second etch process is performed on the top electrode layer 780, the resistance switching film 760, the auxiliary film 740 and the bottom electrode layer 720 (see FIG. 11), with the hard mask 82 in place, until the etch stop layer 60 is reached to form at least one top electrode 78 underlying the hard mask 82, at least one switching layer 76 underlying the top electrode 78, at least one auxiliary layer 74 underlying the switching layer 76, and at least one bottom electrode 72 underlying the auxiliary layer 74 and overlying the etch stop layer 60, the barrier layer 63 and the BEVA 64 (two top electrodes, two switching layers, two auxiliary layers and two bottom electrodes are exemplarily shown). The hard mask 82 is kept after the second etch process and remains being disposed over the top electrode 78. The top electrode 78, the switching layer 76, the auxiliary layer 74 and the bottom electrode 72 cooperate to form the resistive memory device 700 that is similar to the resistive memory device 100 of FIG. 1 or the resistive memory device 200 of FIG. 2. The switching layer 76 reversibly changes between a HRS that corresponds to a first data state and a LRS that corresponds to a second data state depending upon a voltage applied across the switching layer 76. The second etch process may be conducted by one or more etching processes (for example but not limited to, a wet etching process, a dry etching process, or a combination thereof) to form the top electrode 78, the switching layer 76, the auxiliary layer 74 and the bottom electrode 72

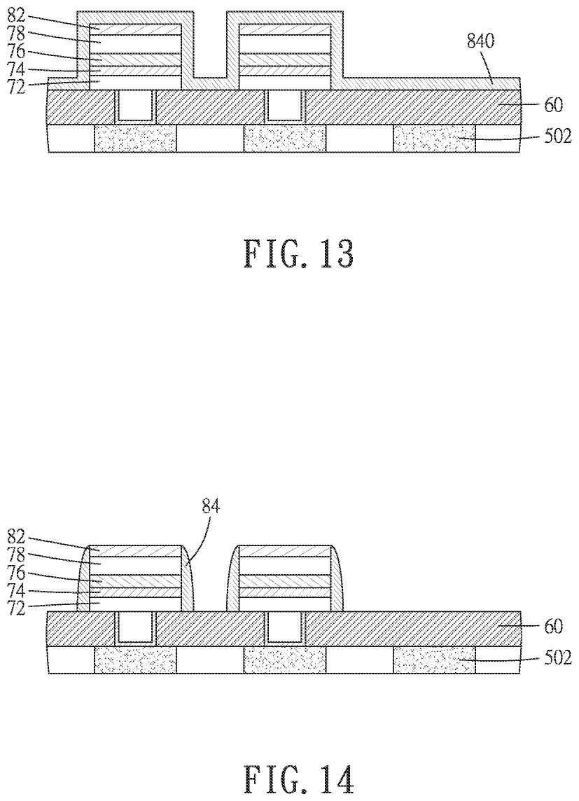

Referring to FIG. 4 and the example illustrated in FIG. 13, the method 400 proceeds to step S09, where a spacer layer 840 is formed to cover the structure of FIG. 12. Specifically, the spacer layer 840 overlies the etch stop layer 60 and the hard mask 82, and covers sidewalls of the top surface 78, the switching layer 76, the auxiliary layer 74 and the bottom electrode 72. In some embodiments, the spacer layer 840 includes, for example but not limited to, silicon oxide, silicon nitride, silicon oxynitride, other dielectrics, other suitable materials, or combinations thereof. In some embodiments, the spacer layer 840 is formed conformally, and is formed by CVD, PVD, other suitable deposition processes, or combinations thereof.

Referring to FIG. 4 and the example illustrated in FIG. 14, the method 400 proceeds to step S10, where a third etch process is performed on the spacer layer 840 (see FIG. 13) to etch back the spacer layer 840 and to form at least one spacer 84 (two spacers are exemplarily shown). The spacer 84 includes a pair of spacer segments respectively on opposite sidewalls of the top electrode 78, respectively on opposite sidewalls of the switching layer 76, respectively on opposite sidewalls of the auxiliary layer 74, and respectively on opposite sidewalls of the bottom electrode 72. In some embodiments, the spacer segments are further disposed respectively on opposite sidewalls of the hard mask 82 that are even with the opposite sidewalls of the top electrode 78. In some embodiments, the spacer 84 may extend laterally along sidewalls of the resistive memory device 700 in a closed path to completely enclose the resistive memory device 700, and this is not visible within the sectional view of FIG. 14. In some embodiments, the third etch process is an anisotropic etching process (for example but not limited to, an anisotropic dry etching process) that includes applying one or more etchants on the spacer layer 840 to remove horizontal segments of the spacer layer 840 without removing most vertical segments of the spacer layer 840. It is noted that corners of the vertical segments of the spacer layer 840 may be etched during the third etch process so the spacer segments have rounded corners.

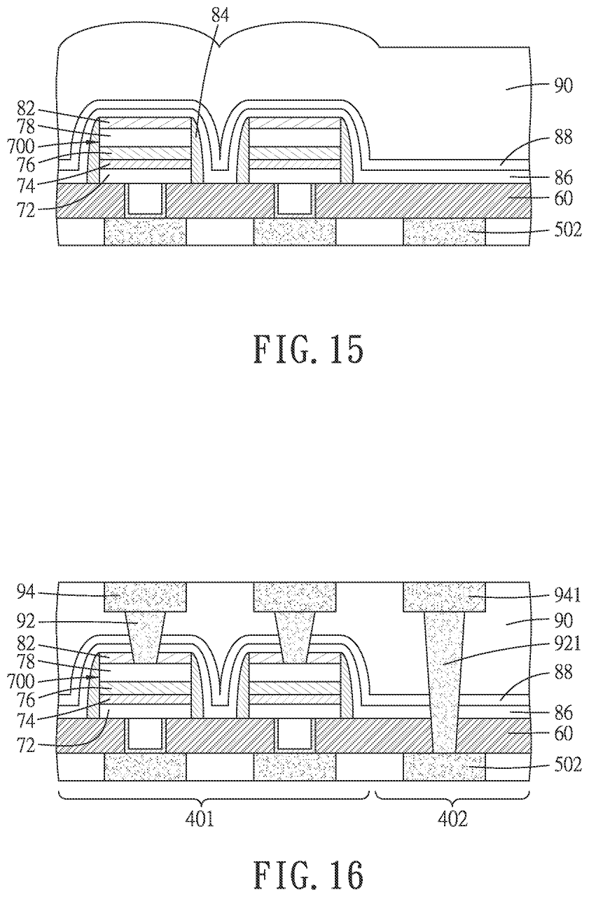

Referring to FIG. 4 and the example illustrated in FIG. 15, the method 400 proceeds to step S11, where a capping layer 86 is formed to cover the etch stop layer 60, the spacer 84 and the hard mask 82, a buffer layer 88 is formed to cover the capping layer 86, and an upper ILD layer 90 is formed to cover the buffer layer 88. The capping layer 86 further covers sidewalls of the spacer 84. In some embodiments, each of the capping layer 86, the buffer layer 88 and the upper ILD layer 90 is formed by one or more conformal deposition processes. In some embodiments, the capping layer 86 includes, for example but not limited to, silicon carbide, silicon nitride, other carbides, other nitrides, other dielectrics, other suitable materials, or combinations thereof. In some embodiments, the capping layer 86 is formed by CVD, PVD, other suitable deposition processes, or combinations thereof. In some embodiments, the buffer layer 88 includes, for example but not limited to, tetraethoxysilane (TEOS) or other materials suitable for adhesion. In some embodiments, the buffer layer 88 is formed by low pressure chemical vapor deposition process (LPCVD) or other suitable deposition processes. In some embodiments, the upper ILD layer 90 includes, for example but not limited to, silicon oxide, a low-k dielectric material, other suitable materials for an ILD layer, or combinations thereof. In some embodiments, the upper ILD layer 90 is formed by PVD, CVD, sputtering, other suitable deposition processes, or combinations thereof. After the upper ILD layer 90 is formed, a planarization process may be subsequently performed on the upper ILD layer 90 to make a top surface of the upper ILD layer 90 planar or substantially planar (see FIG. 16). In some embodiments, the planarization process is performed by, for example but not limited to, a CMP or other suitable planarization processes.

Referring to FIG. 4 and the example illustrated in FIG. 16, the method 400 proceeds to step S12, where at least one TEVA 92 is formed to overlay the top electrode 78, and at least one upper wire 94 is formed to overlay the TEVA 92 in the upper ILD layer 90 (two TEVAs and two upper wires are exemplarily shown). In some embodiments, the formation of the TEVA 92 and the upper wire 94 may be realized by a dual-damascene scheme where (i) one or more etching processes are performed to form a via recess and a trench; (ii) a deposition process is performed to fill a conductive material layer in the via recess and the trench; and (iii) a planarization process is performed to remove an excess portion of the conductive material layer to form the TEVA 92 and the upper wire 94. In some embodiments, the formation of the TEVA 92 and the upper wire 94 may be realized by a single-damascene scheme where (i) one or more etching processes are performed to form a via recess; (ii) a deposition process is performed to fill a conductive material in the via recess; (iii) a planarization process is performed to remove an excess portion of the conductive material to form the TEVA 92; (iv) a deposition process is performed to form an additional upper ILD layer on the upper ILD layer 90 and the TEVA 92; (v) an etching process is performed on the additional upper ILD layer to form a trench over and exposing the TEVA 92; (vi) a deposition process is performed to fill a conductive material in the trench; and (vii) a planarization is performed to remove an excess portion of the conductive material to form the upper wire 94. In some embodiments, the etching process for forming the via recess is performed to etch into the upper ILD layer 90, the buffer layer 88, the capping layer 86 and the hard mask 82 to form the via recess over and exposing the top electrode 78, and may be realized by one or more etching processes (for example but not limited to, a wet etching process, a dry etching process, or a combination thereof). In some embodiments, the deposition process for filling the conductive material includes, for example but not limited to, CVD, PVD, electroless plating, electroplating, other suitable plating or deposition processes, or combinations thereof. In some embodiments, the planarization process is performed by, for example but not limited to, a CMP or other suitable planarization processes.

In some embodiments, the TEVA 92 is electrically connected to the top electrode 78, and includes, for example but not limited to, copper, aluminum, tungsten, aluminum copper, other metals, other suitable conductive materials, or combinations thereof. In some embodiments, the upper wire 94 overlies and is electrically connected to the TEVA 92, and the upper wire 94 includes, for example but not limited to, copper, aluminum, titanium, tantalum, aluminum copper, titanium nitride, tantalum nitride, other metals, other suitable conductive materials, or combinations thereof. In a scenario where the dual-damascene scheme is adopted, the TEVA 92 and the upper wire 94 may include the same material.

Further, in some embodiments, an additional via 921 and additional upper wire 941 in the logic region 402 may be formed together with the processes for forming the TEVA 92 and the upper wire 94 in the memory region 401, and may have the same materials as the TEVA 92 and the upper wire 94, respectively. The additional via 921 extends through the upper ILD layer 90, the buffer layer 88, the capping layer 86 and the etch stop layer 60, to reach and contact the lower wire 502 in the logic region 402. A top surface of the additional via 921 is even or substantially even with a top surface of the TEVA 92. The additional upper wire 941 overlies and is electrically connected to the additional via 921. In some embodiments, the logic region 402 may accommodate a logic device (not shown) that may be, for example but not limited to, an IGFET, or a MOSFET. In some embodiments, the logic device may support operation of the resistive memory device 700, for example, with respect to data reading and/or writing in connection with the resistive memory device 700.

After the semiconductor device of FIG. 16 is manufactured, a voltage is applied across the bottom electrode 72 to the top electrode 78, i.e., a forming voltage across the switching layer 76, to form one or more conductive paths in the switching layer 76, i.e., a process of electroforming is performed on the resistive memory device 700.

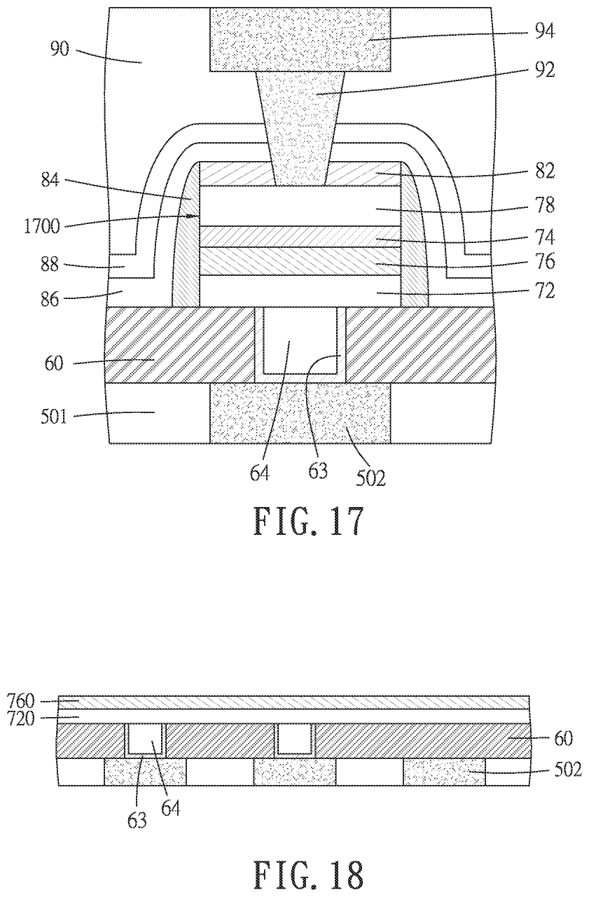

FIG. 17 is a schematic sectional view illustrating a semiconductor device that includes a resistive memory device 1700 in accordance with some embodiments. The resistive memory device 1700 is similar to the resistive memory device 700 shown in FIG. 16, but differs from the resistive memory device 700 in that the auxiliary layer 74 overlies the switching layer 76 and the top electrode 78 overlies the auxiliary layer 74. In some embodiments, the auxiliary layer 74 is sandwiched between the top electrode 78 and the switching layer 76, rather than being sandwiched between the switching layer 76 and the bottom electrode 72 as is the case of the resistive memory device 700 shown in FIG. 16. In this scenario, the top electrode 78 is a relatively inert electrode in comparison with the bottom electrode 72. In some embodiments, the top electrode 78 includes a metal, and the auxiliary layer 74 includes a nitride of the metal. In some embodiments, the top electrode 78 includes ruthenium, and the auxiliary layer 74 includes ruthenium nitride. Other suitable materials for the top electrode 78 and the auxiliary layer 74 are within the contemplated scope of the present disclosure. In some embodiments, components of the resistive memory device 1700 may have dimensions similar to those of the resistive memory device 200 of FIG. 2. For example, in some embodiments, the top electrode 78 has a thickness that ranges from about 0.1 nm to about 500 nm, the auxiliary layer 74 has a thickness that ranges from about 0.1 nm to about 10 nm, the switching layer 76 has a thickness that ranges from about 0.1 nm to about 100 nm, and the bottom electrode 72 has a thickness that ranges from about 0.1 nm to about 500 nm. In some embodiments, a ratio of the thickness of the top electrode 78 to the thickness of the auxiliary layer 74 ranges from about 0.1:1 to about 5000:1.

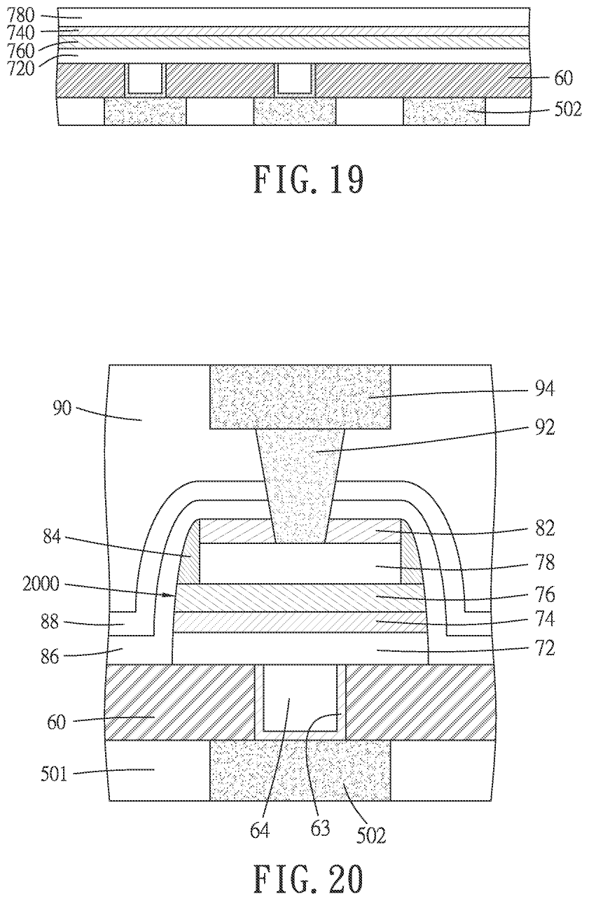

In some embodiments, a method for manufacturing a semiconductor device that includes the resistive memory device 1700 is similar to the method 400 of FIG. 4, but differs from the method 400 in the order of steps related to forming the auxiliary film 740 and the resistance switching film 760. Referring FIG. 18, after step S05 of FIG. 4 for forming at least one BEVA 64 and at least one barrier layer 63 is performed (see FIG. 9), a bottom electrode layer 720 is first formed on the etch stop layer 60, the BEVA 64 and the barrier layer 63, and a resistance switching film 760 is then formed on the bottom electrode layer 720. In some embodiments, the bottom electrode layer 720 is formed to cover the etch stop layer 60, the BEVA 64 and the barrier layer 63, and the resistance switching film 760 is formed to cover the bottom electrode layer 720. After that, referring to FIG. 19, an auxiliary film 740 is formed on the resistance switching film 760, and a top electrode layer 780 is formed on the auxiliary film 740. In some embodiments, the auxiliary film 740 is formed to cover the resistance switching film 760, and the top electrode layer 780 is formed to cover the auxiliary film 740.

In some embodiments, the bottom electrode layer 720 includes a relatively active material in terms of oxygen ions in comparison with the top electrode layer 780, and includes, for example but not limited to, copper, aluminum, tungsten, tantalum, titanium, compounds thereof (e.g., titanium nitride or tantalum nitride), other conductive materials, or combinations thereof. Other suitable materials for the bottom electrode layer 720 are within the contemplated scope of the present disclosure. In some embodiments, a material of the resistance switching film 760 is similar to that of the resistance switching film 760 discussed previously with respect to step S06 and FIG. 10, and relevant details are omitted herein for the sake of brevity. In some embodiments, each of the bottom electrode layer 720 and the resistance switching film 760 is formed by, for example but not limited to, CVD, PVD, electroless plating, electroplating, sputtering, other suitable plating or deposition process, or combinations thereof.

In some embodiments, the top electrode layer 780 is conductive and includes a metal, and the auxiliary film 740 includes a nitride of the metal. In some embodiments, the top electrode layer 780 includes ruthenium, and the auxiliary film 740 includes ruthenium nitride. Other suitable materials for the top electrode layer 780 and the auxiliary film 740 are within the contemplated scope of the present disclosure. Regarding formation of the auxiliary film 740 on the resistance switching film 760, many approaches may be adopted. One approach is to deposit a layer of metal (e.g., ruthenium) on the resistance switching film 760, and then perform a nitriding process on the layer of metal. Since the nitriding process has been explained with respect to step S06 and FIG. 10, details of the same are omitted herein for the sake of brevity. Another approach is to directly deposit the auxiliary film 740, such as a film of ruthenium nitride, on a top surface of the resistance switching film 760 by using, for example but not limited to, PVD, ALD, CVD, other suitable deposition processes, or combinations thereof. In some embodiments, the top electrode layer 780 is formed by, for example but not limited to, CVD, PVD, electroless plating, electroplating, sputtering, other suitable plating or deposition process, or combinations thereof.

The subsequent steps of the method for manufacturing the semiconductor device that includes the resistive memory device 1700 are similar to steps S08 to S12 of the method 400 of FIG. 4 explained in company with FIGS. 12 to 16, so details thereof are omitted herein for the sake of brevity.

FIG. 20 is a schematic sectional view illustrating a semiconductor device that includes a resistive memory device 2000 in accordance with some embodiments. The resistive memory device 2000 is similar to the resistive memory device 700 shown in FIG. 16, but differs from the resistive memory device 700 in that a dimension of the top electrode 78 a horizontal direction of FIG. 20 is smaller than dimensions of the switching layer 76, the auxiliary layer 74 and the bottom electrode 72 in the same direction. Moreover, the spacer 84 overlies the switching layer 76, rather than overlying the etch stop layer 60 as shown in FIG. 16. The spacer 84 includes a pair of spacer segments respectively bordering opposite sidewalls of the top electrode 78. In some embodiments, the spacer segments respectively border opposite sidewalls of the hard mask 82 that are aligned with the opposite sidewalls of the top electrode 78.

In some embodiments, a method for manufacturing a semiconductor device that includes the resistive memory device 2000 is similar to the method 400 of FIG. 4, but differs from the method 400 in that the second etch process is performed to form only the top electrode 78, and an additional etch process is performed to form the switching layer 76, the auxiliary layer 74 and the bottom electrode 72 after formation of the spacer 84.

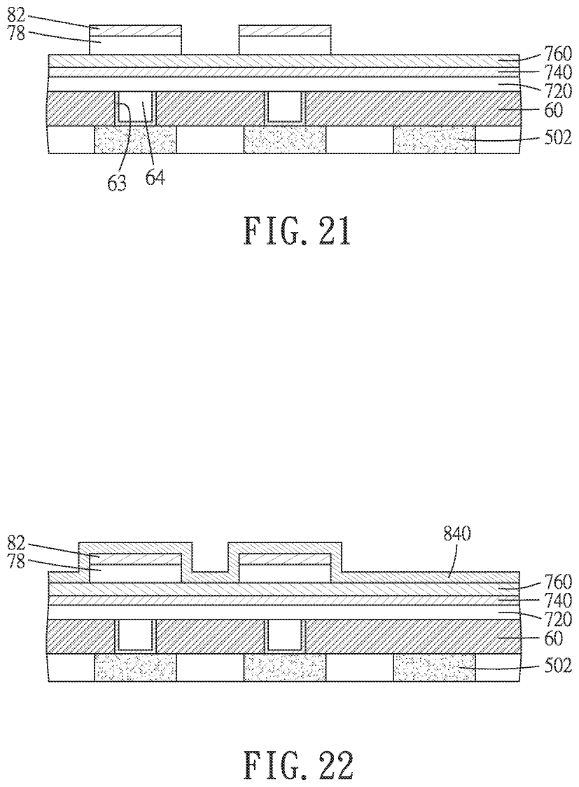

Referring FIG. 21, after step S07 of FIG. 4 for forming a resistance switching film 760 and a top electrode layer 780 is performed (see FIG. 11), at least one hard mask 82 is formed to cover at least one electrode part of the top electrode layer 780 that overlies the BEVA 64 and the lower wire 502 (two hard masks and two electrode parts are exemplarily shown). Subsequently, a second etch process is performed to etch into the top electrode layer 780 with the hard mask 82 in place until the resistance switching film 760 is reached to form at least one top electrode 78 underlying the hard mask 82 (two top electrodes are exemplarily shown). In some embodiments, the resistance switching film 760 serves as an etch stop layer for the second etch process. In some embodiments, the second etch process may partially etch into the resistance switching film 760. In some embodiments, a material of the hard mask 82 and the second etch process are similar to those explained with respect to step S08 and FIG. 12, so details thereof are omitted herein for the sake of brevity.

Referring to FIG. 22, after the top electrode 78 is formed, a spacer layer 840 is formed to cover the structure of FIG. 21. Specifically, the spacer layer 840 overlies the resistance switching film 760 and the hard mask 82, and covers sidewalls of the top surface 78. In some embodiments, the spacer layer 840 is formed conformally. In some embodiments, a material of and a deposition process for forming the spacer layer 840 are similar to those explained with respect to step S09 and FIG. 13, so relevant details are omitted herein for the sake of brevity.

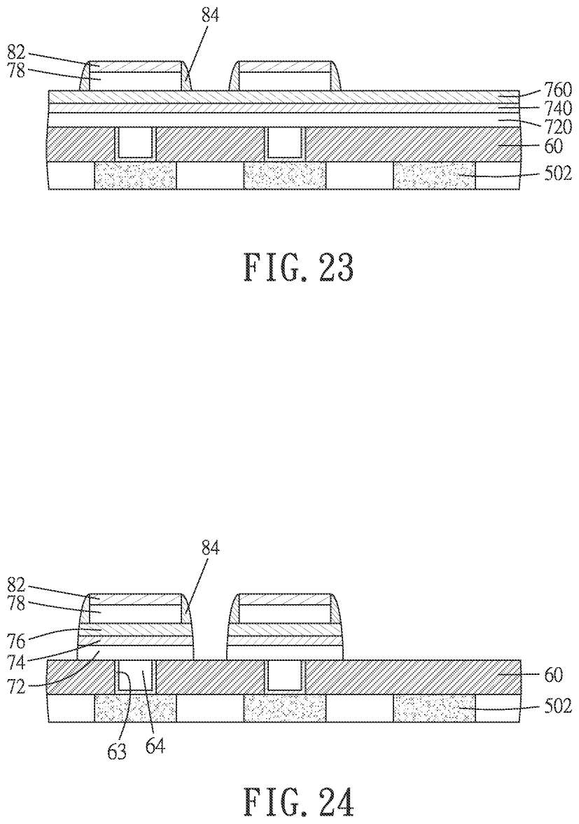

Referring to FIG. 23, after the spacer layer 840 is formed, a third etch process is performed to etch into the spacer layer 840 (see FIG. 22) and form at least one spacer 84 (two spacers are exemplarily shown). The spacer 84 includes a pair of spacer segments respectively on opposite sidewalls of the top electrode 78. In some embodiments, the spacer segments are further disposed respectively on opposite sidewalls of the hard mask 82 that are even with the opposite sidewalls of the top electrode 78. In some embodiments, the third etch process is similar to that explained with respect to step S10 and FIG. 14, so details thereof are omitted herein for the sake of brevity.

Referring to FIG. 24, after the spacer 84 is formed, an additional etch process is performed to etch into the resistance switching film 760, the auxiliary film 740 and the bottom electrode layer 720 with the hard mask 82 and the spacer 84 in place (see FIG. 23) to form a switching layer 76, an auxiliary layer 74 and a bottom electrode 72. The switching layer 76 underlies the top electrode 78, the auxiliary layer 74 underlies the switching layer 72, and the bottom electrode 72 underlies the BEVA 64 and the barrier layer 63. The additional etch process includes, for example but not limited to, applying one or more etchants to etch into the resistance switching film 760, the auxiliary film 740 and the bottom electrode layer 720 until the etch stop layer 60 is reached by the etchant(s).

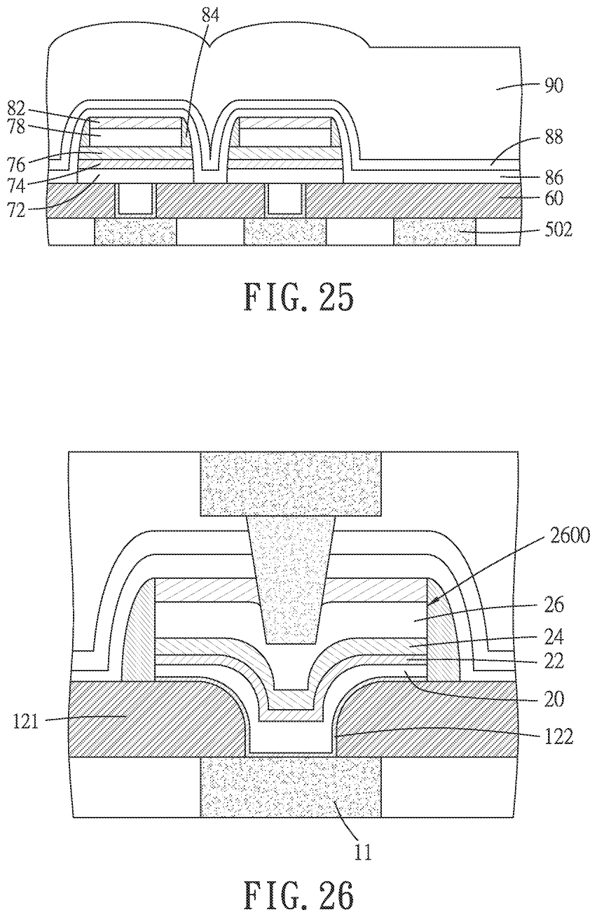

Referring to FIG. 25, after the switching layer 76, the auxiliary layer 74 and the bottom electrode 72 are formed, a capping layer 86 is formed to cover the etch stop layer 60, the spacer 84 and the hard mask 82, a buffer layer 88 is formed to cover the capping layer 86, and an upper ILD layer 90 is formed to cover the buffer layer 88. The capping layer 86 further covers sidewalls of the spacer 84, sidewalls of the switching layer 76, sidewalls of the auxiliary layer 74 and sidewalls of the bottom electrode 72. After the upper ILD layer 90 is formed, a planarization process (e.g., a CMP) may be subsequently performed on the upper ILD layer 90 to make a top surface of the upper ILD layer 90 planar or substantially planar. In some embodiments, materials of and depositions processes for forming the capping layer 86, the buffer layer 88 and the upper ILD layer 90 are similar to those explained with respect to step S11 and FIG. 15, so relevant details are omitted herein for the sake of brevity.

The subsequent step of the method for manufacturing the semiconductor device that includes the resistive memory device 2000 is similar to step S12 of the method of FIG. 4 explained in company with FIG. 16 (i.e., forming at least one TEVA 92 and at least one upper wire 94), so details thereof are omitted herein for the sake of brevity.

FIG. 26 is a schematic sectional view illustrating a semiconductor device that includes a resistive memory device 2600 in accordance with some embodiments. The resistive memory device 2600 is similar to the resistive memory device 200 shown in FIG. 2, but differs from the resistive memory device 200 in that each of the top electrode 26, the switching layer 24, the auxiliary layer 22 and the bottom electrode 20 substantially has a “gull-wing shape.” The auxiliary layer 22 is sandwiched between the bottom electrode 20 and the switching layer 24. In some embodiments, the bottom electrode 20 includes ruthenium and the auxiliary layer 22 includes ruthenium nitride. Moreover, the etch stop layer 121 has rounded corners and the bottom electrode 20 has an extended electrode part that extends through the etch stop layer 121 toward the lower wire 11 and that serves as a BEVA. In some embodiments, the semiconductor device further includes a barrier layer 122 that cups an underside of the bottom electrode 20 so as to cover a bottom of the bottom electrode 20. The barrier layer 122 contacts the bottom electrode 20, the lower wire 11 and the etch stop layer 121, and blocks a material of the bottom electrode 20 from migrating out of the bottom electrode 20 to surrounding structures (e.g., the lower wire 11 underneath the bottom electrode 20).

In some alternative embodiments related to the example of FIG. 26, the switching layer 24 is disposed on the bottom electrode 20, the auxiliary layer 22 is disposed on the switching layer 24, and the top electrode 26 is disposed on the auxiliary layer 22. In other words, the auxiliary layer 22 is sandwiched between the switching layer 24 and the top electrode 26, rather than being sandwiched between the switching layer 24 and the bottom electrode 20 as shown in FIG. 26. In this scenario, the top electrode 26 includes a metal (e.g., ruthenium), the auxiliary layer 22 includes a nitride of the metal (e.g., ruthenium nitride), and the bottom electrode 20 is a relatively active electrode (e.g., including titanium nitride, tantalum nitride or tungsten) in comparison with the top electrode 26.

As described above, in a method for manufacturing a semiconductor device of the present disclosure, an auxiliary layer that includes a nitride of a metal is formed between a switching layer and one of a top electrode and a bottom electrode that includes the metal. As shown in FIG. 2, 20 or 26, a resistive memory device includes an auxiliary layer that is disposed between the switching layer and the bottom electrode which includes a metal, and a material of the auxiliary layer is a nitride of the metal. For example, the bottom electrode includes ruthenium and the auxiliary layer includes ruthenium nitride. Alternatively, as shown in FIG. 17, the auxiliary layer is disposed between the switching layer and the top electrode, and it may be that the top electrode includes ruthenium while the auxiliary layer includes ruthenium nitride. With the auxiliary layer sandwiched between the switching layer and a relatively inert electrode of the top and bottom electrodes, oxygen ions generated in the switching layer when the resistive memory device is applied with a voltage are more prone to moving toward the relatively active electrode of the top and bottom electrodes (e.g., the top electrode of FIG. 2, 20 or 26, or the bottom electrode of FIG. 17). As a result, a forming voltage utilized for the electroforming and a set voltage utilized for the set process in the resistive memory device can be reduced, and the switching power consumed by the resistive memory device may also be reduced. Moreover, an endurance (i.e., the number of write/erase cycles) of the resistive memory device may be promoted with the existence of the auxiliary layer between the switching layer and one of the top electrode and the bottom electrode. In addition, a process flow for forming the resistive memory device is compatible with a process flow for forming a logic device, such as a transistor, thereby facilitating realization of the 1T1R cell configuration.

In accordance with some embodiments of the present disclosure, a resistive memory device includes a bottom electrode, a switching layer disposed over the bottom electrode, a top electrode disposed over the switching layer, and an auxiliary layer disposed between the switching layer and one of the top electrode and the bottom electrode. The one of the top electrode and the bottom electrode includes a metal and is a relatively inert electrode in comparison with the other one of the top electrode and the bottom electrode. The auxiliary layer includes a nitride of the metal.

In accordance with some embodiments of the present disclosure, the one of the top electrode and the bottom electrode includes ruthenium, and the auxiliary layer includes ruthenium nitride.

In accordance with some embodiments of the present disclosure, the auxiliary layer overlies and is directly on the bottom electrode, the switching layer overlies and is directly on the auxiliary layer, and the top electrode overlies and is directly on the switching layer.

In accordance with some embodiments of the present disclosure, the switching layer overlies and is directly on the bottom electrode, the auxiliary layer overlies and is directly on the switching layer, and the top electrode overlies and is directly on the auxiliary layer.

In accordance with some embodiments of the present disclosure, a dimension of the top electrode in a direction is smaller than dimensions of the switching layer, the auxiliary layer and the bottom layer in the same direction.

In accordance with some embodiments of the present disclosure, the other one of the top electrode and the bottom electrode is a relatively active electrode in comparison with the one of the top electrode and the bottom electrode, and includes at least one material selected from the group consisting of copper, aluminum, tungsten, tantalum, titanium, titanium nitride and tantalum nitride.

In accordance with some embodiments of the present disclosure, the switching layer includes at least one material selected from the group consisting of hafnium oxide, zirconium oxide, aluminum oxide, silicon nitride and aluminum nitride.

In accordance with some embodiments of the present disclosure, the auxiliary layer has a thickness that ranges from about 0.1 nanometers to about 10 nanometers.

In accordance with some embodiments of the present disclosure, each of the top electrode, the switching layer, the auxiliary layer and the bottom electrode has a gull-wing shape.

In accordance with some embodiments of the present disclosure, a semiconductor device includes a lower wire, a resistive memory device that overlies the lower wire, that is connected to the lower wire, and that includes a bottom electrode disposed over the lower wire, a switching layer disposed over the bottom electrode, a top electrode disposed over the switching layer, and an auxiliary layer sandwiched between the switching layer and one of the top electrode and the bottom electrode, and a spacer that includes a pair of spacer segments respectively bordering opposite sidewalls of the top electrode.

In accordance with some embodiments of the present disclosure, the one of the top electrode and the bottom electrode is a relatively inert electrode in comparison with the other one of the top electrode and the bottom electrode, and includes a metal, the auxiliary layer including a nitride of the metal.

In accordance with some embodiments of the present disclosure, the one of the top electrode and the bottom electrode includes ruthenium, and the auxiliary layer includes ruthenium nitride.

In accordance with some embodiments of the present disclosure, the semiconductor device further includes a bottom electrode via (BEVA) that overlies the lower wire. The resistive memory device is disposed on the BEVA. The BEVA extends from the bottom electrode to the lower wire.

In accordance with some embodiments of the present disclosure, the semiconductor device further includes a barrier layer that covers a bottom and sidewalls of the BEVA, and that contacts the BEVA and the lower wire.

In accordance with some embodiments of the present disclosure, the semiconductor device further includes a hard mask that is disposed on the top electrode. The pair of spacer segments further respectively border opposite sidewalls of the hard mask that are aligned with the opposite sidewalls of the top electrode.

In accordance with some embodiments of the present disclosure, the pair of spacer segments further respectively border opposite sidewalls of the switching layer, respectively border opposite sidewalls of the auxiliary layer, and respectively border opposite sidewalls of the bottom electrode.

In accordance with some embodiments of the present disclosure, a dimension of the top electrode in one direction is smaller than dimensions of the switching layer, the auxiliary layer and the bottom electrode in the same direction, and the spacer overlies the switching layer.

In accordance with some embodiments of the present disclosure, a method for manufacturing a semiconductor device includes: forming a bottom electrode layer over a substrate that includes a lower interlayer dielectric (ILD) layer and a lower wire within the lower ILD layer; forming an auxiliary film, a resistance switching film and a top electrode layer over the bottom electrode layer, wherein the auxiliary film is formed between the resistance switching layer and one of the bottom electrode layer and the top electrode layer, and the top electrode layer is formed over the auxiliary layer and the resistance switching layer; forming a hard mask on the top electrode layer and overlying the lower wire; and performing at least one etch process to etch into the top electrode layer, the resistance switching layer, the auxiliary layer and the bottom electrode layer with the hard mask in place, so as to form a top electrode, a switching layer, an auxiliary layer and a bottom electrode.

In accordance with some embodiments of the present disclosure, forming an auxiliary film includes performing a nitriding process on a metal to form a nitride of the metal.

In accordance with some embodiments of the present disclosure, forming an auxiliary film includes directly depositing the auxiliary film that includes a nitride of a metal on one of the bottom electrode layer and the resistance switching film.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A resistive memory device comprising:
a bottom electrode;
a switching layer disposed over the bottom electrode;
a top electrode disposed over the switching layer; and
an auxiliary layer disposed between the switching layer and one of the top electrode and the bottom electrode,
wherein the one of the top electrode and the bottom electrode includes a metal and is a relatively inert electrode in comparison with the other one of the top electrode and the bottom electrode, and wherein the auxiliary layer includes a nitride of the metal.

2. The resistive memory device as claimed in claim 1, wherein the one of the top electrode and the bottom electrode includes ruthenium, and the auxiliary layer includes ruthenium nitride.

3. The resistive memory device as claimed in claim 1, wherein the auxiliary layer overlies and is directly on the bottom electrode, the switching layer overlies and is directly on the auxiliary layer, and the top electrode overlies and is directly on the switching layer.

4. The resistive memory device as claimed in claim 1, wherein the switching layer overlies and is directly on the bottom electrode, the auxiliary layer overlies and is directly on the switching layer, and the top electrode overlies and is directly on the auxiliary layer.

5. The resistive memory device as claimed in claim 1, wherein a dimension of the top electrode in a direction is smaller than dimensions of the switching layer, the auxiliary layer and the bottom layer in the same direction.

6. The resistive memory device as claimed in claim 1, wherein the other one of the top electrode and the bottom electrode is a relatively active electrode in comparison with the one of the top electrode and the bottom electrode, and includes at least one material selected from the group consisting of copper, aluminum, tungsten, tantalum, titanium, titanium nitride and tantalum nitride.

7. The resistive memory device as claimed in claim 1, wherein the switching layer includes at least one material selected from the group consisting of hafnium oxide, zirconium oxide, aluminum oxide, silicon nitride and aluminum nitride.

8. The resistive memory device as claimed in claim 1, wherein the auxiliary layer has a thickness that ranges from about 0.1 nanometers to about 10 nanometers.

9. The resistive memory device as claimed in claim 1, wherein each of the top electrode, the switching layer, the auxiliary layer and the bottom electrode has a gull-wing shape.

10. A semiconductor device comprising:
a lower wire;
a resistive memory device that overlies the lower wire, that is connected to the lower wire, and that includes a bottom electrode disposed over the lower wire, a switching layer disposed over the bottom electrode, a top electrode disposed over the switching layer, and an auxiliary layer sandwiched between the switching layer and one of the top electrode and the bottom electrode; and
a spacer that includes a pair of spacer segments respectively bordering opposite sidewalls of the top electrode.

11. The semiconductor device as claimed in claim 10, wherein the one of the top electrode and the bottom electrode is a relatively inert electrode in comparison with the other one of the top electrode and the bottom electrode, and includes a metal, the auxiliary layer including a nitride of the metal.

12. The semiconductor device as claimed in claim 10, wherein the one of the top electrode and the bottom electrode includes ruthenium, and the auxiliary layer includes ruthenium nitride.

13. The semiconductor device as claimed in claim 10, further comprising a bottom electrode via (BEVA) that overlies the lower wire, the resistive memory device being disposed on the BEVA, the BEVA extending from the bottom electrode to the lower wire.

14. The semiconductor device as claimed in claim 11, further comprising a barrier layer that covers a bottom and sidewalls of the BEVA, and that contacts the BEVA and the lower wire.

15. The semiconductor device as claimed in claim 10, further comprising a hard mask that is disposed on the top electrode, the pair of spacer segments further respectively bordering opposite sidewalls of the hard mask that are aligned with the opposite sidewalls of the top electrode.

16. The semiconductor device as claimed in claim 10, wherein the pair of spacer segments further respectively border opposite sidewalls of the switching layer, respectively border opposite sidewalls of the auxiliary layer, and respectively border opposite sidewalls of the bottom electrode.

17. The semiconductor device as claimed in claim 10, wherein a dimension of the top electrode in one direction is smaller than dimensions of the switching layer, the auxiliary layer and the bottom electrode in the same direction, and the spacer overlies the switching layer.

18. A method for manufacturing a semiconductor device, comprising:
forming a bottom electrode layer over a substrate that includes a lower interlayer dielectric (ILD) layer and a lower wire within the lower ILD layer;
forming an auxiliary film, a resistance switching film and a top electrode layer over the bottom electrode layer, wherein the auxiliary film is formed between the resistance switching layer and one of the bottom electrode layer and the top electrode layer, and the top electrode layer is formed over the auxiliary layer and the resistance switching layer;
forming a hard mask on the top electrode layer and overlying the lower wire; and
performing at least one etch process to etch into the top electrode layer, the resistance switching layer, the auxiliary layer and the bottom electrode layer with the hard mask in place, so as to form a top electrode, a switching layer, an auxiliary layer and a bottom electrode.

19. The method as claim in claim 18, wherein forming an auxiliary film includes performing a nitriding process on a metal to form a nitride of the metal.

20. The method as claim in claim 18, wherein forming an auxiliary film includes directly depositing the auxiliary film that includes a nitride of a metal on one of the bottom electrode layer and the resistance switching film.
